(19) United States
(12) Patent Application Publication
(10) Pub. No.: US 2013/0092807 A1
(43) Pub. Date: Apr. 18, 2013

(54) MOUNTING APPARATUS FOR STORAGE DEVICE

(71) Applicants: Yun-Lung CHEN, Tu-Cheng (TW); Liang-Chin WANG, Tu-Cheng (TW); Li TONG, Wuhan City (CN); Jun-Zhi XU, Wuhan City (CN)

(72) Inventors: Yun-Lung CHEN, Tu-Cheng (TW); Liang-Chin WANG, Tu-Cheng (TW); Li TONG, Wuhan City (CN); Jun-Zhi XU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/541,695

(22) Filed: Jul. 4, 2012

(30) Foreign Application Priority Data
Oct. 14, 2011 (CN) 201110311238.2

(51) Int. Cl. H05K 7/14; H05K 7/20

(52) U.S. Cl. 248/220.21

(57) ABSTRACT

A mounting apparatus includes a receiving case; a mounting tray received in the receiving case, and a securing tray configured for securing a storage device. The mounting tray includes a bottom plate. A clipping assembly and a limiting portion are located on the bottom plate. The securing tray includes a clamping panel and a handle extending from the clamping panel. A blocking tab is located on the handle and engaged with the limiting portion. The clamping panel is attached to the bottom plate and engaged with the clipping assembly, and the handle is deformable for disengaging the blocking tab from the limiting portion.

### BACKGROUND

1. Technical Field

The present disclosure relates to a mounting apparatus for mounting a storage device.

2. Description of Related Art

In computers, a storage device is typically secured to a drive bracket with screws. A significant drawback to this is that the insertion and removal of screws is cumbersome and time consuming. In addition, a tool such as a screwdriver is usually required. Moreover, the screws can be lost during assembly or disassembly. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus, and a storage device in accordance with an embodiment.

FIG. 2 is an exploded, isometric view of a securing tray, a mounting tray, and the storage device of FIG. 1.

FIG. 3 is similar to FIG. 2, with two securing members are secured to the securing tray.

FIG. 4 is similar to FIG. 1, with the securing tray is received in a receiving case of FIG. 1.

FIG. 5 is an assembled view of the mounting apparatus and the storage device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

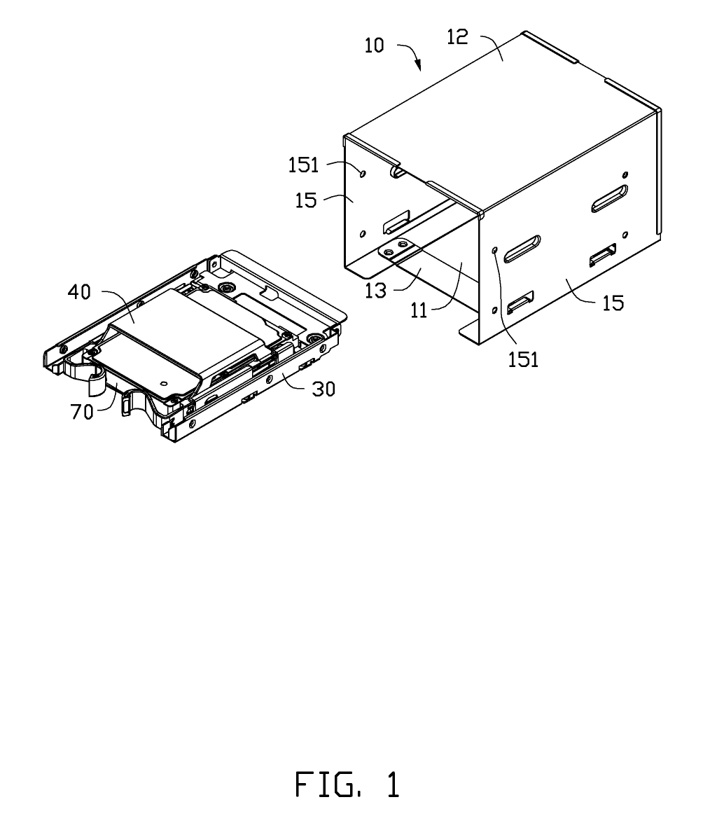

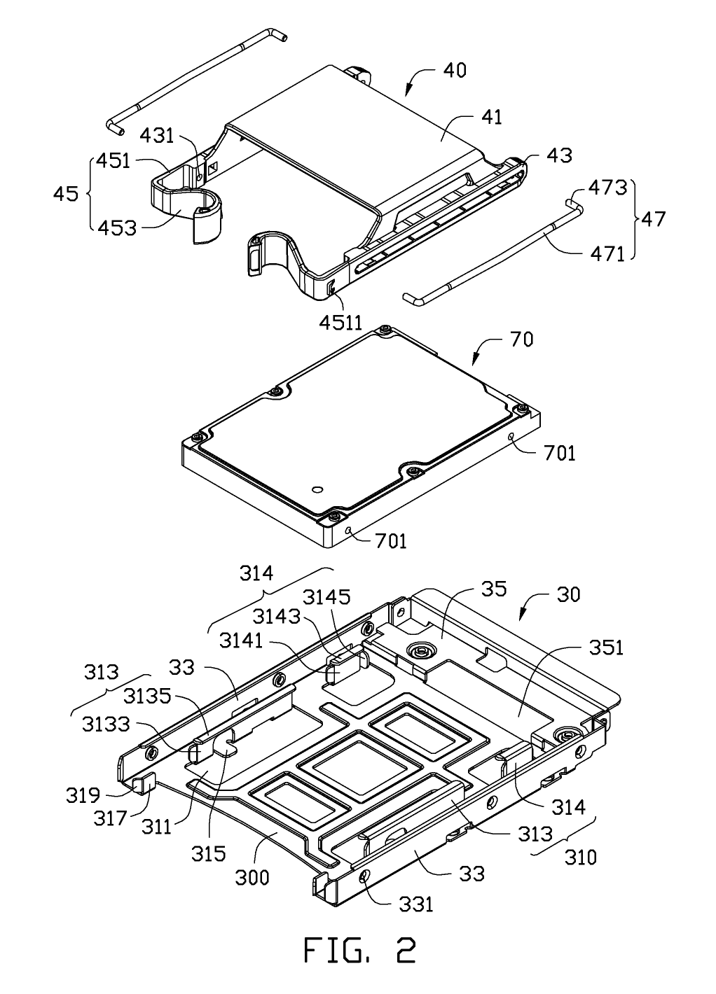

Referring to FIGS. 1-2, one embodiment of a mounting apparatus includes a receiving case 10, a mounting tray 30, and a securing tray 40. The mounting tray 30 and the securing tray 40 secure a storage device 70 to the receiving tray 10. In one embodiment, the storage device 70 may be a hard disk or an optical disk drives. The storage device 70 is a 2.5 inch storage device. Two fixing holes 701 are defined in opposite sides of the storage device 70, and a connector (not shown) is connected to the storage device 70.

The receiving case 10 includes a top panel 12, a bottom panel 13 opposite to the top panel 12, and two substantially parallel side panels 15. The top panel 12, the bottom panel 13, and the two side panels 15 cooperatively define a receiving space 11. A plurality of through holes 151 are defined in each of the two side panels 15.

Referring to FIG. 2, a mounting space 300 is defined in the front of the mounting tray 30. The mounting tray 30 includes a bottom plate 31 and two side plates 33 extending from opposite edges of the bottom plate 31. A plurality of heating dissipating holes 311 is defined in the bottom plate 31, and a plurality of mounting holes 331 is defined in each of the two side plates 33.

A clipping assembly 310, including a first clipping member 313 and a second clipping member 314, is located between the bottom plate 31 and each of the two side plates 33. The first clipping member 313 includes a first positioning portion 3133 and a first resisting portion 3135 extending from a top edge of the positioning portion 3133. In one embodiment, the first resisting portion 3135 is substantially perpendicular to the first positioning portion 3133. The second clipping member 314 includes a second positioning portion 3141, a second resisting portion 3143, and a blocking portion 3145. In one embodiment, the second resisting portion 3143 is substantially perpendicular to the second positioning portion 3141. The first positioning portion 3133 extends from a first one of the plurality of heating dissipating holes 311, and the second positioning portion 3141 extends from a second one of the plurality of heating dissipating holes 311. In one embodiment, the first positioning portion 3133 and the second positioning portion 3141 are located on a plane substantially parallel to the side plate 33.

Two supporting tabs 315 are located on the bottom plate 31. In one embodiment, each of the two supporting tabs 315 extends from the first one of the plurality of heat dissipating holes 311. Each of the two supporting tabs 315 is substantially parallel to the first resisting portion 3135. Two limiting portions 317, each with a guiding portion 319, are located on opposite sides of the mounting space 300. The guiding portion 319 is slanted towards the side plate 33. A transferring portion 35, with a cutout 351, extends from the bottom plate 31 and is located on the back side of the mounting tray 30.

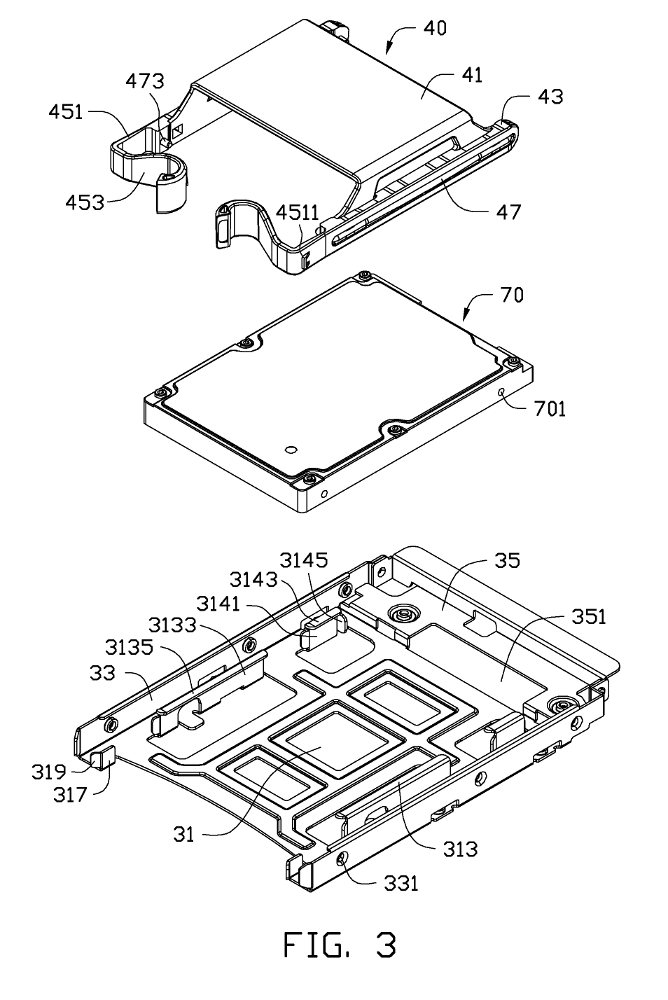

Referring to FIG. 3, the securing tray 40 includes a connecting panel 41, two substantially parallel clamping panels 43 connected to the connecting panel 41, two handles 45, and two securing members 47. Each of the clamping panels 43 defines a securing hole 431. The two handles 45 are integrally formed from the two clamping panels 43, and each of the two handles 45 includes a resilient portion 451 and an operating portion 453 connected to the resilient portion 451. In one embodiment, the operating portion 453 is curved. A blocking tab 4511 is located between the resilient portion 451 and the operating portion 453. Each of the two securing members 47 includes a main body 471 and two securing portions 473 extending from opposite end of the main body 471 and substantially perpendicular to the main body 471.

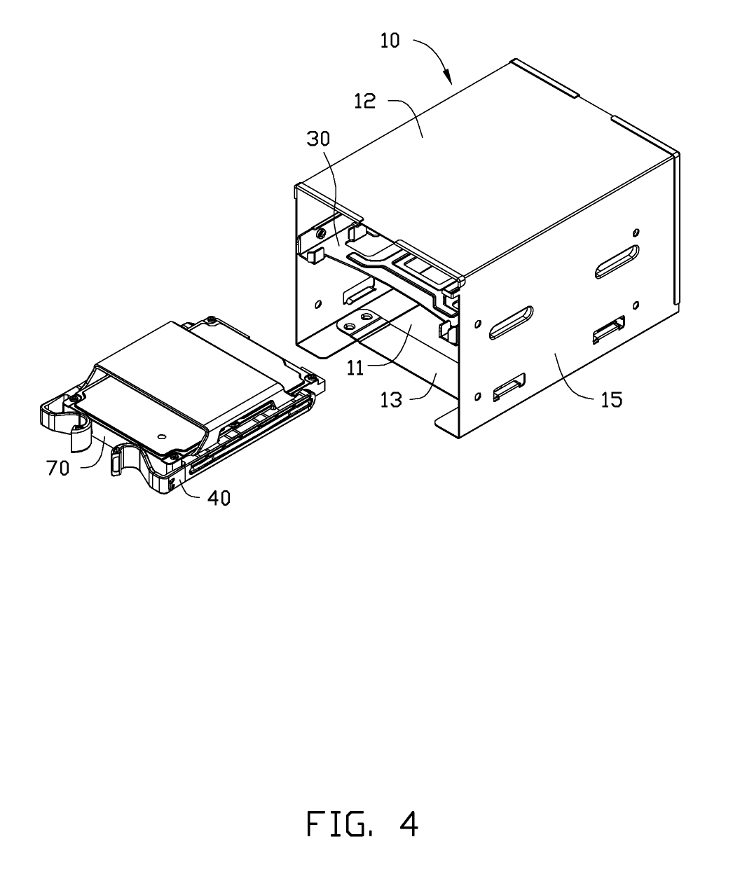

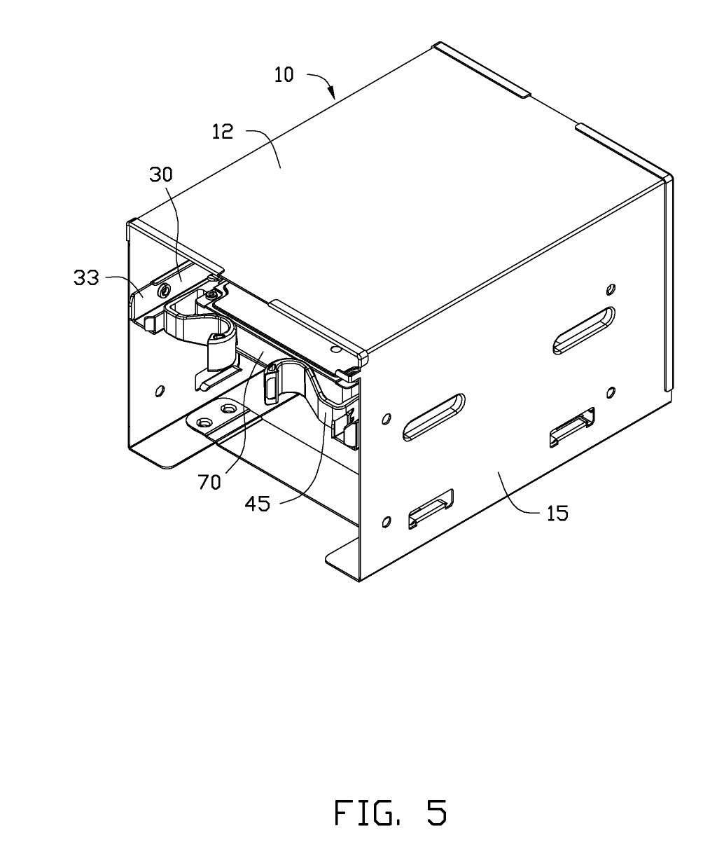

Referring to FIGS. 4 and 5, in assembly, the mounting tray 30 is received in the receiving space 11. The mounting holes 331 are aligned with the through holes 151. The mounting tray 30 is screwed to the receiving case 10.

The storage device 70 is placed on the bottom of the securing tray 40 and moved towards the securing tray 40. Thus, the storage device 70 is located between the two clamping panels 43. The fixing holes 701 are aligned with the securing holes 431. The securing portion 473 is engaged in the fixing holes 701 and the securing holes 431 to secure the storage device 70 to the securing tray 40.

The securing tray 40 with the storage device 70 is located between the two guiding portions 319. The two operating portions 453 are operated to deform the two resilient portions 451. The securing tray 40 is moved in a direction towards the mounting space 300, and the two clamping panels 43 are clamped between the two clipping assemblies until the back portions of the two clamping panels 43 abut the blocking portion 3145. The resilient portions 451 are released, and the blocking tabs 4511 are clipped with the limiting portions 317, to prevent the securing tray 40 from moving. Therefore, the securing tray 40 with the storage device 70 is secured to the receiving case 10, and a connector (not shown) of the storage device 70 is received in the cutout 351.

In disassembly, the operating portions 453 are operated to deform the two resilient portions 451, and the two blocking portions 4511 are disengaged from the two limiting portions 317. The securing tray 40 is moved in a second direction opposite to the first direction, and the securing members 47 are detached from the fixing holes 701 and the securing holes 431. Therefore, the storage device 70 is removed from the securing tray 40.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus for a storage apparatus, the mounting apparatus comprising:
a mounting tray comprising a bottom plate, a clipping assembly, and a limiting portion located on the bottom plate; and
a securing tray configured for securing the storage device, wherein the securing tray comprises a clamping panel, a handle extending from the clamping panel, and a blocking tab located on the handle and engaged with the limiting portion; the clamping panel is engaged with the clipping assembly, and the handle is deformable for disengaging the blocking tab from the limiting portion.

2. The mounting apparatus of claim 1, wherein the handle comprises a resilient portion extending from the clamping panel, and the blocking tab is located on the resilient portion.

3. The mounting apparatus of claim 2, wherein the handle further comprises an operating portion extending from the resilient portion, and the operating portion is configured for deforming the resilient portion.

4. The mounting apparatus of claim 1, further comprising a securing member, wherein the clamping panel defines a securing hole, and the securing member is engaged in the securing hole and a fixing hole of the storage device to secure the storage device to the clamping panel.

5. The mounting apparatus of claim 4, wherein the securing member comprises a main body attached to the clamping panel and a securing portion extending from the main body, and the securing portion is substantially perpendicular to the main body.

6. The mounting apparatus of claim 1, wherein the bottom plate defines a heat dissipating hole, the clipping assembly comprises a first clipping member extending from an edge of the heat dissipating hole, the first clipping member comprises a first positioning portion and a first resisting portion extending from the first positioning portion, and the clamping panel abuts the first positioning portion and the first resisting portion.

7. The mounting apparatus of claim 6, wherein the first clipping member further comprises a supporting tab substantially parallel to the bottom plate, and the supporting tab extends towards the heat dissipating hole and supports the storage device.

8. The mounting apparatus of claim 6, wherein the clipping assembly further comprises a second clipping member located on the bottom plate, the mounting tray further comprises a side plate substantially perpendicular to the bottom plate, and the first clipping member and the second clipping member are aligned with a straight line substantially parallel to the side plate.

9. The mounting apparatus of claim 8, wherein the second clipping member comprises a blocking portion substantially perpendicular to the side plate, and the blocking portion abuts the clamping panel preventing the securing tray from moving.

10. The mounting apparatus of claim 1, wherein the mounting tray further comprises a guiding portion extending from the limiting portion, and the guiding portion is slanted from the limiting portion.

11. A mounting apparatus for a storage apparatus, the mounting apparatus comprising:
a receiving case;
a mounting tray, received in the receiving case, comprising a clipping assembly and a limiting portion;
a securing tray comprising a clamping panel, a handle extending from the clamping panel, and a blocking tab located on the handle and engaged with the limiting portion; and
a securing member attached to the clamping panel to secure a storage device to the securing tray;
wherein the securing tray is received in the mounting tray, the clamping panel is engaged with the clipping assembly, and the handle is deformable for disengaging the blocking tab from the limiting portion.

12. The mounting apparatus of claim 11, wherein the handle comprises a resilient portion extending from the clamping panel, and the blocking tab is located on the resilient portion.

13. The mounting apparatus of claim 12, wherein the handle further comprises an operating portion extending from the resilient portion, and the operating portion is configured for deforming the resilient portion.

14. The mounting apparatus of claim 11, wherein the clamping panel defines a securing hole, the securing member is engaged in the securing hole and a fixing hole of the storage device, to secure the storage device to the clamping panel.

15. The mounting apparatus of claim 11, wherein the securing member comprises a main body attached to the clamping panel and a securing portion extending from the main body, and the securing portion substantially perpendicular to the main body.

16. The mounting apparatus of claim 11 wherein the mounting tray comprising a bottom plate, the bottom plate defines a heat dissipating hole, the clipping assembly comprises a first clipping member extending from an edge of the heat dissipating hole, the first clipping member comprises a first positioning portion and a first resisting portion extending from the first positioning portion, and the clamping panel abuts the first positioning portion and the first resisting portion.

17. The mounting apparatus of claim 16, wherein the first clipping member further comprising a supporting tab substantially parallel to the bottom plate, and the supporting tab extends towards the heat dissipating hole and supports the storage device.

18. The mounting apparatus of claim 16, wherein the clipping assembly further comprises a second clipping member located on the bottom plate, the mounting tray further comprises a side plate substantially perpendicular to the bottom plate, and the first clipping member and the second clipping member are aligned with a straight line substantially parallel to the side plate.

19. The mounting apparatus of claim 18, wherein the second clipping member comprises a blocking portion substantially perpendicular to the side plate, and the blocking portion abuts the clamping panel preventing the securing tray from moving.

20. The mounting apparatus of claim 11, wherein the mounting tray further comprises a guiding portion extending from the limiting portion, and the guiding portion is slanted from the limiting portion.
